(19) United States
(12) Patent Application Publication
(10) Pub. No.: US 2011/0221145 A1
(43) Pub. Date: Sep. 15, 2011

(54) ELECTROSTATIC CHUCK

(76) Inventor: Mehmet A. Akbas, Cheshire, CT (US)

(21) Appl. No.: 12/998,706

(22) PCT Filed: Nov. 24, 2009
(86) PCT No.: PCT/US09/06253

§ 371 Date: May 20, 2011

Related U.S. Application Data
(60) Provisional application No. 61/200,240, filed on Nov. 25, 2008.

(51) Int. Cl. H01L 21/687; H05K 13/04

(52) U.S. Cl. 279/128; 29/593

(57) ABSTRACT

An electrostatic chuck featuring a chuck support structure, and a plurality of discrete electrostatic components. Each of the electrostatic components features at least one termination attached to an electrode on an electrically insulating material. At least some of the discrete electrostatic components are removably attached to the chuck support structure or to a substrate that is interposed between said chuck support structure and the electrostatic components.

### CROSS-REFERENCE TO RELATED PATENTS AND PATENT APPLICATIONS

This patent document claims the benefit of U.S. Provisional Patent Application Ser. No. 61/200,240, filed on Nov. 25, 2008.

### TECHNICAL FIELD

The present invention relates to machines used to support and/or transport wafers of semiconductor material during processing of the latter to make useful products such as integrated circuits or solar cells. More particularly, it pertains to the devices or “chucks” used to support or transport such wafers using electrostatic force to hold or clamp the wafer in place during or between the processing steps, sometimes referred to as an “electrostatic chuck.”

### BACKGROUND ART

The prior art of manufacturing electrostatic chucks has included deposition of thin film metallic electrodes and ceramic dielectric layers onto a support substrate using thin film technology such as physical vapor deposition (PVD), chemical vapor deposition (CVD) or plasma-enhanced chemical vapor deposition (PECVD). The resulting electrostatic wafer chucks are monolithic integrated devices.

U.S. Pat. No. 4,692,836 to Suzuki discloses an electrostatic chuck where the electrode is divided into a plurality of split electrodes. In an arrangement where one electrode is encapsulated in an electrically insulating or dielectric material, and the other is connected electrically to the wafer to be processed, the Suzuki invention addresses the problem where the wafer is not perfectly flat, but instead is warped up or down. The electrostatic force varies as the square of the applied voltage, and also as the inverse of the distance or gap between the wafer and the dielectric layer. One of the objects of this patent is to render the wafer “flat”, at least for processing. When the wafer is curved or warped such that the periphery or edges contact the dielectric but the center does not, the electrostatic attraction needs to be concentrated in the center and little or none applied at the periphery. Suzuki teaches various means to apply non-uniform electrostatic force to the wafer. In one example, the electrode is made up of a plurality of spaced concentric split electrodes, or the electrode features a plurality of circumferentially spaced radial members. Alternatively, the thickness of the dielectric member is varied. Variable resistors are provided for applying the same or different DC voltages to respective split electrodes.

U.S. Pat. No. 5,535,090 to Sherman discloses an electrostatic chuck featuring a plurality of small electrostatic structures for holding an electrically conductive work piece forming a plate of a capacitor.

U.S. Pat. No. 5,880,923 to Hausmann notes that modern electrostatic chucks typically do more than simply hold a wafer in place for processing; they often heat or cool the wafer. Often, a heat transfer gas is supplied to the backside of the wafer, in the gap or space between the wafer and the chuck. Thus, modern chucks often have a lip of material designed to engage with the periphery of the wafer. Nevertheless, this lip is where much of the heat transfer gas leaks out. Haumann addresses this matter by applying greater voltage, and thus greater electrostatic force, to the zone at or near the periphery of the chuck, and less to the middle or center of the chuck. He does this by embedding beneath the surface of the chuck a number of electrodes defining a number of chucking zones. In one embodiment, the chucking zones are concentric rings of electrically insulating material. The electrodes are energized by a number of non-zero voltages, thereby creating a variable, non-zero chucking force in each of the chucking zones. Wafer chucking zones of differing force improve uniformity of heat transfer gas layer distribution.

U.S. Pat. No. 5,384,682 to Watanabe is concerned with avoiding contamination of wafers and with quickly dissipating the electrostatic force once the device stops applying voltage to the electrode(s). Watanabe notes that, unless electrical current leaks or dissipates, the built-up electrical charge tends to remain after the application of voltage is suspended, and thus, the wafer is still electrostatically adhered to the chuck. He addresses both of these problems by providing a protective film to protect the wafers from contamination from the chuck. He furthermore engineers the volume resistivity of the insulating layer, the dielectric constant of the insulating layer, the thickness of the insulating layer, and the gap between the wafer and the chuck, if any, to cause the electrostatic force to decrease in a short period of time after the applied voltage is shut off. He discloses Al₂O₃, Si₃N₄, AlN or SiC as candidate substrate materials.

U.S. Pat. No. 5,324,053 to Kubota discloses an electrostatic chuck that utilizes a high dielectric constant material (at least having a value of 50). The electrostatic force is proportional to the dielectric constant of the electrical insulator in which is embedded the electrode to which voltage is applied. The problem is that high dielectric materials tend to have low volume electrical resistivity. Thus, they tend to have high or large “leak currents”, which can ultimately lead to dielectric breakdown. Kubota solves this problem by interposing a high volume resistivity material in the form of a layer between the work piece (the wafer) and the high dielectric constant material. The high dielectric constant material has a dielectric constant of at least 50 and can be made from barium titanate, lead titanate, zirconium titanate, PLZT and the like.

U.S. Pat. No. 5,426,558 to Sherman disclose a method for making an electrostatic chuck featuring sandwiching two substantially planar dielectric members around a brazing compound that becomes an electrode after the assembly is heated and cooled. In a chuck featuring a metal heating element and having a CTE mismatch between this heating element and the dielectric materials, Sherman proposes to solve this problem by interposing a plurality of metal pins between the two materials. The metal pins may be brazed to the metal heating element.

U.S. Pat. No. 5,968,273 to Kadomura et al. addresses the CTE mismatch problem by making the heater, referred to as the “temperature adjusting jacket” out of an aluminum composite material. The composite aluminum material is prepared by treatment of aluminum with inorganic fibers under a high pressure. The composite aluminum has a thermal conductivity close to that of aluminum, but a CTE that is less than that of aluminum.

U.S. Pat. No. 5,191,506 to Logan et al. addresses the CTE mismatch problem by providing an electrically conductive electrostatic pattern disposed onto a multilayer ceramic (MLC) substrate, which is bonded to a MLC support structure. A heat sink base supports the entire structure and a MLC isolation layer is placed on top of the electrostatic metal pattern to isolate the wafer from coming in contact with the metal pattern. Brazing is the preferred method for bonding the heat sink base to the bottom of the support structure. The material selected for the heat sink base is critical because it must match the thermal expansion of the MLC substrates. KOVAR, an iron/nickel/cobalt alloy (a registered trademark of the Westinghouse Electric Co.), is the preferred material.

### DISCLOSURE OF THE INVENTION

In accordance with the instant invention, and in contrast with the prior art, an electrostatic silicon wafer chuck can be constructed by populating a wafer chuck with discrete electrostatic components.

### BRIEF DESCRIPTION OF THE DRAWINGS

FIG. 1 is a cross-sectional view of a portion of a front surface of an electrostatic chuck of the instant invention gripping a silicon wafer.

FIG. 2 is a cross-sectional view of a portion of a front surface of an electrostatic chuck of the instant invention gripping a silicon wafer, and represents an alternate embodiment of the instant invention.

FIG. 3 is a cross-sectional view of a bipolar electrostatic attraction component of the instant invention.

FIG. 4 is a photograph according to the Example of electrostatic components that have been sintered but have not yet been terminated.

FIG. 5 is a photograph according to the Example of a simple device to show proof-of-concept for the instant electrostatic chuck design with independent surface-mount components.

### MODES FOR CARRYING OUT THE INVENTION

Prior art electrostatic chucks typically are prepared by depositing one or more electrostatic attraction regions featuring electrodes and dielectric materials to the chuck support material, thereby forming an integrated device. The electrostatic attraction components are not normally removable from the support structure. In addition, the electrostatic attraction components of the prior art may feature relatively large pieces of the dielectric material. As the electrostatic chucks typically heat up to during wafer processing, the respective thermal expansion coefficients (“CTEs”) of the materials making up the electrostatic attraction components and the support structure must be taken into account. More specifically, if the CTE mismatch between the two materials is too great, cracking or other catastrophic failure may result. Thus, matching the respective CTEs has been a major consideration in the prior art, which unfortunately acts as a constraint on the choice of materials used for the respective parts of the chuck.

Furthermore, thin film techniques suitable for making integrated electrodes and dielectric layers (prior art) are limited to simple dielectric chemistries such as Si—O, Si—N and Ta—O. The dielectric properties of these simple chemistries are far inferior to those of tailored dielectric compositions used in the discrete capacitor industry. For example, the relative permittivity of class I, II and III dielectrics can range from 100 to 20,000 respectively. This high relative permittivity is very desirable to increase the electrostatic force applied on the wafer, and they cannot be achieved with simple chemistries suitable for thin film deposition techniques.

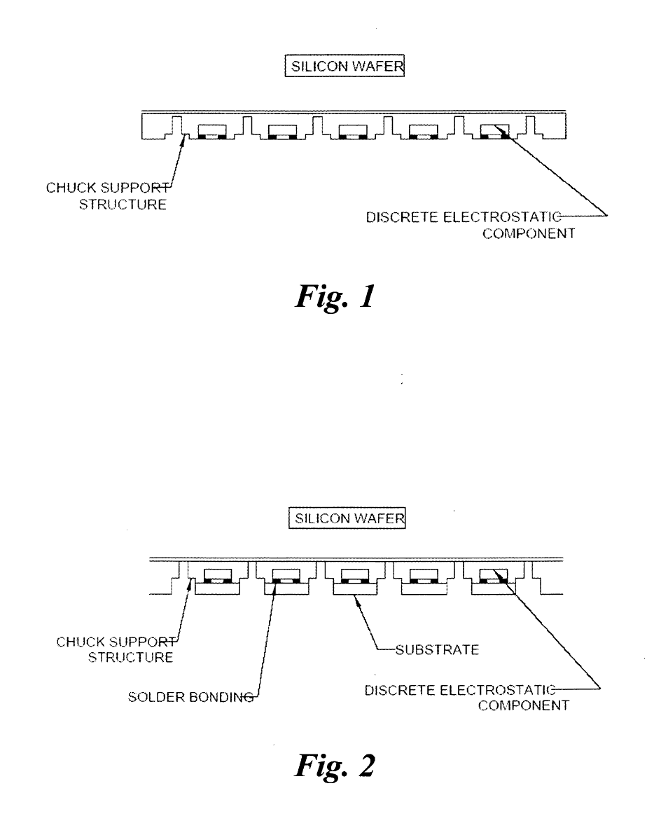

In accordance with the instant invention, and in contrast to the prior art, an electrostatic silicon wafer chuck can be constructed by populating a wafer chuck with discrete electrostatic components. FIG. 1, for example, is a schematic drawing of one embodiment of the inventive electrostatic chuck. Electrostatic components are attached directly to the wafer chuck. By separating the wafer chuck from the electrostatic components, both can be optimized independently for their own functionality. That is, the wafer chuck can be built from mechanically and thermally stable materials to provide superior wafer support, and the electrostatic components can be manufactured using engineered novel dielectric materials to optimize chucking and de-chucking functions.

By separating these two constituents as the embodiments of the instant invention do, the CTE mismatch issue is much less of a concern. This is so is because (i) the electrostatic attraction components, being discrete, can be made much smaller than previously, and (ii) attachment by interposing a brazing or soldering layer may act as a compliant layer that can absorb some of the strain induced at elevated temperature due to CTE mismatch. Furthermore, with no materials limitations due to thin film processing capability, a wide range of materials with tailored properties can be used both for the chuck support structure and the electrostatic components.

Thus, designers are now freer to engineer each constituent to optimize its performance. For example, the support structure can now be optimized in terms of its important properties or functions, e.g., high thermal conductivity, high stiffness, etc. Similarly, the electrostatic attraction components can be optimized for high dielectric constant, low leakage current, low contamination potential, etc.

Electrostatic components may or may not be in contact with the silicon wafer itself. Their function is limited to generate the electrostatic attraction force to hold the silicon wafer. The chuck structure will support the silicon wafer attracted by the discrete components. Discrete electrostatic components can be built by well-established thick and thin film processing techniques including but not limited to tape casting, wet processing and various chemical and physical vapor deposition techniques. These manufacturing techniques are well established and widely used by the multi layer ceramic and the thin film capacitor industry.

The electrostatic chuck can be built by populating the chuck support structure by a number of discrete electrostatic components as required by the design. Each discrete component is attached onto a metallic electrode deposited onto the chuck support structure. A computer-based control unit can independently adjust applied voltage to each individual component, hence adjusting the magnitude of the electrostatic force applied to the silicon wafer. Alternatively, discrete components can be attached onto an insulating substrate with internal metallization. Such substrates are manufactured by Low Temperature Co-fired Ceramic (LTCC) technology and are widely used by the electronics industry. The resulting substrate populated with discrete components can then be mounted onto a wafer chuck structure. FIG. 2 shows a schematic drawing of this alternate or second embodiment of the invention.

In a third embodiment of the invention, a discrete bipolar electrostatic attraction component can be manufactured using well-established thick and thin film processing techniques, including but not limited to tape casting, wet processing and various chemical and physical vapor deposition techniques. The design of this discrete electrostatic component is shown schematically in FIG. 3.

This FIG. 3 includes a dielectric base, metallic electrodes and a final thin dielectric layer. Metallic electrodes are connected to outside terminations. Internal electrodes are in bipolar configuration to optimize chucking and de-checking efficiency. Bipolar configuration eliminates the need for electrostatic component to contact the silicon wafer during operation. Therefore, there is no net current flow through the wafer, eliminating the risk for device damage. Terminations may be plated with various metal chemistries such as nickel and tin to provide an improved soldering surface. Alternatively, terminations can be manufactured from stable precious metals such as gold, palladium or platinum or their alloys. Electrostatic components with terminations not suitable for soldering can be attached using conductive epoxy.

An embodiment of the instant invention will now be described with even greater specificity with reference to the following example.

### Example

This example device demonstrates the feasibility and functionality of an embodiment of the invention. A water-based ceramic slurry was formulated to build the electrostatic components. The formulation of the slurry is as follows:

### 66 wt. % FERRO AD-302L X7R Dielectric Powder

### 21 wt. % JONCRYL 1532 Latex Binder

### 3 wt. % DARVAN 821A Dispersant

8 wt. % de-ionized Water

### 1.6 wt. % DF-16 Surfactant

### 0.4 wt. % RHODOLINE 622 De-foamer

All ingredients were loaded into a ceramic ball mill and ground for 96 hours at 50 rpm. The resulting slurry was filtered through a 20-micron absolute filter and slow rolled for 24 hours (3-5 rpm) in a glass jar for de-airing.

The electrostatic components were built using wet cast thick film technology. This included casting the 15-micron thick dielectric layers and drying the resulting thick film using warm filtered air. This casting and drying sequence continued to build a 400-micron thick base dielectric layer.

A bipolar configuration metal electrode was then screen printed onto the dielectric layer using 70 wt. % Pd/30-wt. % Ag metal electrode ink. The screen-printed electrode layer was also dried using warm filtered air.

Finally, a 15-micron thick dielectric layer was cast on top of the printed electrodes. The wet buildup was dried, singulated and heat-treated to remove organic components through a binder burnout cycle.

The resulting green electrostatic components were sintered at 1130° C. for 6 hours to obtain ceramic chips.

Both ends of the chips were terminated using fire-on silver paste.

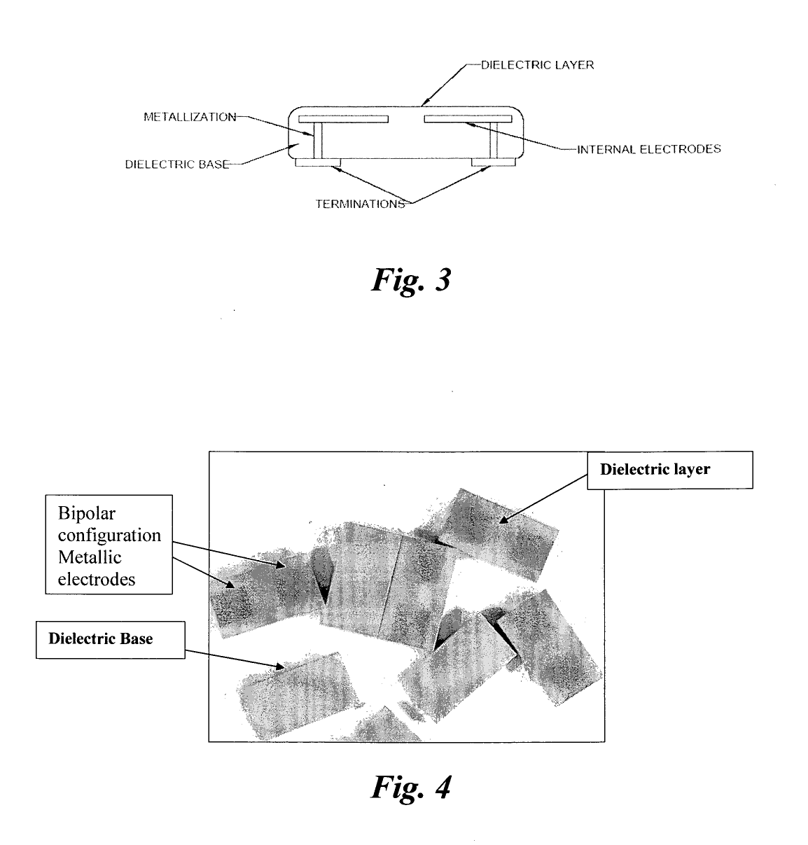

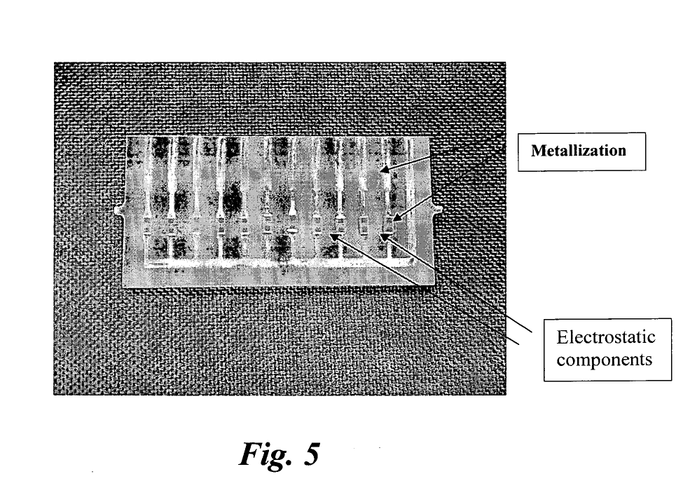

The terminations were then electroplated with consecutive layers of Ni and Sn to enable electrostatic components to be solder mounted. The above-explained processes are widely used in manufacturing multi layer ceramic capacitors in industry, and are well known to those who are skilled in the field. FIG. 4 is the photograph of the chips.

Performance of the chips was evaluated by flow soldering eleven of these chips onto a substrate with plated metallization to apply high voltage across the electrostatic components. The electrostatic components were connected in a parallel configuration. A rectangular wafer grade high purity silicon piece (50 mm by 5 mm by 0.8 mm) was then placed directly onto the chips. The resulting device was connected to a high voltage supply and the chips were charged at 500 V. To demonstrate the attraction force, the device was turned up side down, and the silicon piece was firmly held by the electrostatic components. The silicon piece was immediately released after the voltage was removed, demonstrating the de-chucking.

### INDUSTRIAL APPLICABILITY

The primary advantage of the above-explained design is realized by separating the wafer chuck support structure from the discrete electrostatic attraction components, and therefore both can be optimized independently for their own functionality. Other beneficial features include:
1) A support structure can be manufactured from SiC or composite of Si—SiC or any other known materials with low thermal expansion coefficient, high thermal conductivity, high Young's modulus and low density to provide thermally and mechanically stable support for a silicon wafer. The support structure may include many internal features including but not limited to internal water and helium cooling channels.
2) Discrete electrostatic components can be made using metallic electrodes sandwiched between dielectric layers. These discrete components can be manufactured from a wide range of dielectric compositions with tailored dielectric properties to generate high electrostatic attraction force, short de-chucking time and high device reliability.
3) These discrete components can be built in various body sizes. Therefore, an electrostatic wafer chuck can be populated by a few or thousands of discrete components as required by the design. Silicon wafer chucks can also be populated by discrete components with mixed body sizes.
4) The strength of the electrostatic attraction force applied by each discrete component can be adjusted independently by changing the applied voltage. This enables a silicon wafer flatness adjustment to be made by calibrating every component to the optimum electrostatic attraction force.
5) Each discrete component can be fully tested before use and failed components can easily be replaced, increasing device lifetime and therefore reducing cost.

In addition, since each electrostatic attraction component will contain at least one electrode, the overall electrostatic chuck must necessarily contain a plurality of electrodes. As the electrodes are electrically insulated from one another, there is no requirement that they be raised to the same electrical potential. If the electrodes in one particular region of the electrostatic chuck are raised to a higher electrical potential than other electrodes, the region of the higher electrical potential will exert a greater electrostatic force than other regions, everything else being equal. This ability to tailor the strength of the electrostatic force as a function of region on the surface of the electrostatic chuck is very useful.

Furthermore, it is not necessary to apply the different electrical potential in different electrostatic attraction components. A single electrostatic attraction component may contain multiple electrodes, each energized to a different electrical potential. When a pair of electrodes is given equal and opposite electrical charges, then those electrodes are said to be “bipolar” with respect to each other. This electrode configuration requires no external electrical contact with the wafer to apply electrostatic attraction, and no net charge is built up on the wafer. Chucking and de chucking is rapid. Also, no net current flows through bipolar devices, eliminating the risk for device damage.

An artisan of ordinary skill will appreciate that various modifications may be made to the invention herein described without departing from the scope of the invention as defined in the appended claims.

1. An electrostatic chuck, comprising:
(a) a chuck support structure; and
(b) a plurality of electrostatic components members, the members of the plurality being discrete from one another, all of said components being attached to said chuck support structure and wherein at least some of said components are removably attached to said chuck support structure, each of said electrostatic components comprising at least one electrode attached to an electrically insulating material.

2. An electrostatic chuck, comprising:
(a) a chuck support structure;
(b) a plurality of electrostatic components, said plurality being discrete from one another, each of said electrostatic components comprising at least one termination attached to electrodes on an electrically insulating material; and
(c) a substrate, wherein said chuck support structure is attached to one side of said substrate, and all of said electrostatic components are attached to an opposite side of said substrate, and further wherein at least some of said electrostatic components are removably attached to said substrate.

3. The electrostatic chuck of claim 1, wherein at least one of said electrostatic components is multi-polar.

4. The electrostatic chuck of claim 1, wherein said removably attached comprises brazing, soldering or conductive epoxy.

5. The electrostatic chuck of claim 4, wherein said brazing, soldering or attachment using conductive epoxy is to a metal layer deposited on said chuck support structure.

6. The electrostatic chuck of claim 1, wherein said brazing or soldering is to internal metallization contained in said chuck support structure.

7. The electrostatic chuck of claim 1, wherein said electrostatic components comprise a Class I, II, or III dielectric composition.

8. The electrostatic chuck of claim 1, wherein said plurality of electrostatic components populating said electrostatic chuck is all of the same size.

9. The electrostatic chuck of claim 1, wherein said plurality of electrostatic components populating said electrostatic chuck is of different sizes.

10. The electrostatic chuck of claim 1, wherein said plurality of electrostatic components populating said electrostatic chuck is all of the same composition.

11. The electrostatic chuck of claim 1, wherein said plurality of electrostatic components populating said electrostatic chuck is of different compositions.

12. The electrostatic chuck of claim 1, wherein said support structure comprises at least one material having low thermal expansion coefficient, high thermal conductivity, high Young's modulus and low density.

13. The electrostatic chuck of claim 2, wherein said support structure comprises silicon carbide.

14. The electrostatic chuck of claim 1, wherein said support structure comprises a composite comprising silicon and silicon carbide.

15. A method of making an electrostatic chuck, comprising:
(a) providing a chuck support structure and a plurality of discrete electrostatic components;
(b) testing each of said discrete components; and
(c) populating said chuck support structure with said plurality of discrete electrostatic components, wherein said testing occurs before said populating, and further wherein a discrete electrostatic component that does not pass said testing is replaced before said electrostatic component is populated to said chuck support structure.

16. The electrostatic chuck of claim 2, wherein said removably attached comprises brazing, soldering or conductive epoxy.

17. The electrostatic chuck of claim 16, wherein said brazing, soldering or attachment using conductive epoxy is to a metal layer deposited on said substrate.

18. The electrostatic chuck of claim 16, wherein said brazing or soldering is to internal metallization contained in said substrate.
